(19) United States
(12) Patent Application Publication
(10) Pub. No.: US 2011/0292734 A1
(43) Pub. Date: Dec. 1, 2011

(54) METHOD OF PROGRAMMING NONVOLATILE MEMORY DEVICE

(76) Inventor: Yong Wook KIM, Gyeonggi-do (KR)

(21) Appl. No.: 12/982,796

(22) Filed: Dec. 30, 2010

(30) Foreign Application Priority Data
May 27, 2010 (KR) 10-2010-0049548

(51) Int. Cl. G11C 16/10

(52) U.S. Cl. 365/185.19; 365/185.22

(57) ABSTRACT

A method of programming a semiconductor device includes performing an initial program operation on all memory cells included in a selected memory cell block to set threshold voltages of all the memory cells to a voltage equal to or greater than 0 Volts, erasing memory cells of a selected page in the selected memory cell block, and programming the memory cells of the selected page.

### CROSS-REFERENCE TO RELATED APPLICATION

Priority to Korean patent application number 10-2010-0049548 filed on May 27, 2010, the entire disclosure of which is incorporated by reference herein, is claimed.

### BACKGROUND

Exemplary embodiments relate to a method of programming a nonvolatile memory device and, more particularly, to a method of programming a nonvolatile memory device, which is capable of reducing interference between memory cells when a program operation is performed.

A nonvolatile memory device is equipped with a memory cell array for storing data. The memory cell array includes a plurality of memory cell blocks. Each of the memory cell blocks includes a plurality of memory cells coupled to a plurality of word lines. A group of the memory cells coupled to the same word line is called a page. The memory cell array includes a plurality of pages.

The program operation of a nonvolatile memory device is described below.

FIG. 1 is a flowchart illustrating a known method of programming a nonvolatile memory device.

When the program operation of the nonvolatile memory device is started, an erase operation for erasing all memory cells within a selected memory cell block is first performed at step 12. More particularly, the erase operation is performed so that the threshold voltages of all the memory cells of the selected memory cell block are less than 0 V. After the erase operation is completed, a program operation is performed. The program operation can be performed on a page-by-page basis. For example, where a selected memory cell block includes first to thirty-second pages, the program operation is may be performed sequentially from the first page to the thirty-second page. That is, after the program operation is performed on the first page at step 14, it is determined whether the programmed page is the last page at step 16. If, as a result of the determination, the programmed page is determined not to be the last page, the program operation is performed on a next page at step 18. In such a manner, the program operation can be performed on all pages.

Recently, in order to further improve the degree of integration of semiconductor memory devices, one memory cell is programmed in various levels. Such a memory cell is called a multi-level cell (MLC). In the case of the program operation of a multi-level cell (MLC), when the program operation is started, all memory cells included in a selected memory cell block are first erased.

In order to erase all the memory cells of the selected memory cell block, an erase operation is performed by supplying 0 V to all the word lines of the selected memory cell block and an erase voltage to a well of the selected memory cell block. Accordingly, the threshold voltages of all the memory cells of the selected memory cell block can become 0 V or lower (e.g., −3 V or lower).

Meanwhile, during the time for which the program operation is performed, erased cells or programmed cells can exist near a selected memory cell. As the difference between the threshold voltages of cells existing near the selected memory cell increases, more interference may be generated because of a potential. The interference is further increased because the gap between the cells is narrowed with an increase in the degree of integration of memory devices. In particular, reliability is gradually being deteriorated because of greater interference resulting from the recent high degree of integration of memory devices.

### BRIEF SUMMARY

Exemplary embodiments relate to the reduction of interference between neighboring memory cells by setting all the memory cells of a selected memory cell block to a threshold voltage of a positive voltage and then performing erase and program operations on a page by page basis.

A method of programming a semiconductor device according to an aspect of this disclosure includes performing an initial program operation on all memory cells included in a selected memory cell block to set threshold voltages of all the memory cells to a voltage equal to or greater than 0 Volts, erasing the memory cells of a selected page in the selected memory cell block, and programming the memory cells of the erased page.

A method of programming a semiconductor device according to another aspect of this disclosure includes performing an initial program operation on all memory cells included in a selected memory cell block to set threshold voltages of all the memory cells to a voltage equal to or greater than 0 Volts, erasing the memory cells of a selected page in the selected memory cell block, performing a least significant bit program operation on the memory cells of the selected page, and performing a most significant bit program operation on the memory cells of the selected page.

The initial program operation may be performed in accordance with an Incremental Step Pulse Program (ISPP) method.

The initial program operation may include supplying an initial program voltage to all word lines coupled to all the memory cells and performing a verification operation for determining whether the threshold voltages of all the memory cells have reached a reference voltage.

The method may further include grounding all bit lines coupled to the selected memory cell block, before supplying the initial program voltage to all the word lines.

The initial program voltage may have a voltage level in a range of 18 V to 22 V.

During the verification operation, the reference voltage can be set to a voltage of 0 V or higher or to a voltage of a lowest program state.

In a case where one bit line is coupled to one page buffer, after erasing the memory cells of the selected page, the memory cells of the erased page may be programmed by supplying a ground voltage to selected bit lines and a program-inhibited voltage to unselected bit lines.

In a case where first and second bit lines are coupled to one page buffer, after erasing the memory cells of the selected page, memory cells coupled to the first bit line may be programmed before memory cells coupled to the second bit line are programmed.

In case where one bit line is coupled to one page buffer, after erasing the memory cells of the selected page, the least significant bit program operation and the most significant bit program operation may be performed by supplying a ground voltage to selected bit lines and a program-inhibited voltage to unselected bit lines.

In a case where first and second bit lines are coupled to one page buffer, after erasing the memory cells of the selected page, the least significant bit program operation and the most significant bit program operation may be first performed on memory cells coupled to the first bit line and then on memory cells coupled to the second bit line.

After programming the memory cells of the erased page, if the selected page is not the last page, a next page may be selected, and the erase and program operations are performed on the next page, and if the selected page is the last page, a program operation for the selected memory cell block may be terminated.

The operation of erasing the memory cells of the selected page may not be performed between performing the least significant bit program operation and performing the most significant bit program operation.

During the erasing operation, the threshold voltages of memory cells included in unselected pages of the selected memory cell block may be maintained at a voltage equal to or greater than 0 Volts.

### BRIEF DESCRIPTION OF THE DRAWINGS

FIG. 1 is a flowchart illustrating a known method of programming a nonvolatile memory device;

FIG. 2 is a circuit diagram showing a memory cell array of a nonvolatile memory device according to an exemplary embodiment of this disclosure;

FIG. 3 is a flowchart illustrating a method of programming the nonvolatile memory device according to an exemplary embodiment of this disclosure;

FIG. 4 is a circuit diagram showing a memory cell array of a nonvolatile memory device according to another exemplary embodiment of this disclosure;

FIG. 5 is a flowchart illustrating a method of programming the nonvolatile memory device according to another exemplary embodiment of this disclosure; and

FIG. 6 is a diagram illustrating a shift in the threshold voltages of memory cells when an exemplary method of programming is performed in accordance with this disclosure.

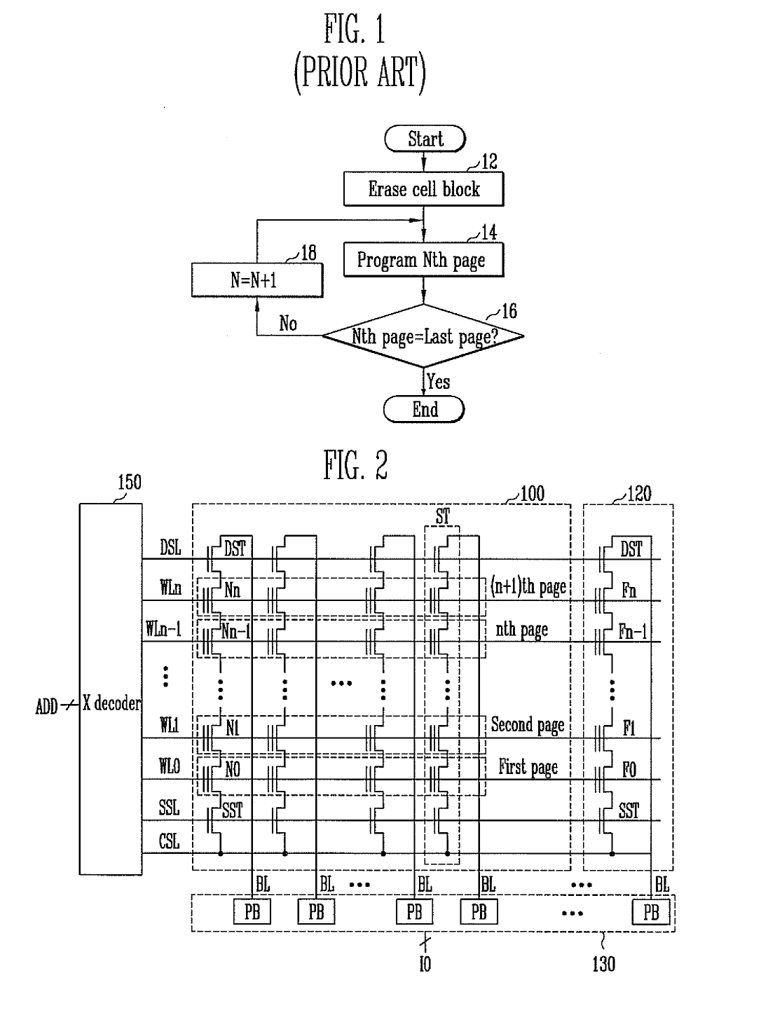

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the exemplary embodiments of the disclosure.

Herein, “n” and “N” are indexes used to reference different elements with similar features. In this capacity, “n” and “N” may be any natural number (e.g., 0, 1, 2, 3, etc.).

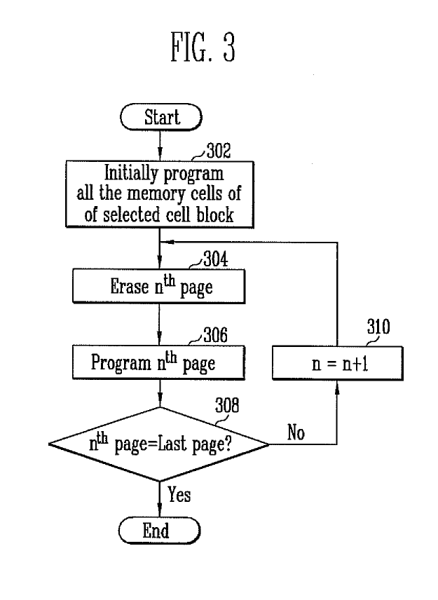

FIG. 2 is a circuit diagram showing a memory cell array of a nonvolatile memory device according to an exemplary embodiment of this disclosure.

The nonvolatile memory device includes a memory cell array 100, a flag cell array 120, a page buffer unit 130, and an X decoder 150.

The memory cell array 100 includes a plurality of strings ST. Each of the strings ST includes a drain select transistor DST, a plurality of memory cells N0 to Nn, and a source select transistor SST which are coupled in series. The gates of the drain select transistors DST included in different strings are coupled together to form a drain select line DSL, and the gates of the source select transistors SST included in different strings are coupled together to form a source select line SSL. The gates of the memory cells N0 to Nn of different strings are respectively coupled together to form a plurality of word lines WL0 to WLn. The drains of the drain select transistors DST included in different strings are coupled to respective bit lines BL, and the sources of the source select transistors SST included in different strings are commonly coupled to a common source line CSL. A group of memory cells coupled to the same word line, from among the memory cells N0 to Nn, is called a page. Accordingly, the number of pages equals the number of word lines.

The flag cell array 120 includes a plurality of flag cells F0 to Fn for storing data of an erase state for the respective pages. The flag cell array 120 has a similar structure as the memory cell array. More specifically, the flag cell array 120 includes one or more strings each including the flag cells F0 to Fn coupled in series between a drain select transistor DST and a source select transistor SST. Each of the flag cells N0 to Nn can be implemented using a flash memory cell. The drains of the drain select transistors DST of the flag cell array 120 are coupled to the page buffer unit 130 via respective bit lines BL, and the sources of the source select transistors SST thereof are coupled to the common source line CSL.

The page buffer unit 130 includes a plurality of page buffers PB. Each page buffer PB is coupled to a corresponding bit line BL. The page buffer unit 130 can supply voltage to the bit line BL in response to data inputted through an I/O terminal 10, or read data stored in the memory cells N0 to Nn or the flag cells F0 to Fn.

The X decoder 150 supplies voltages depending on an operation that is to be performed. For example, the X decoder 150 may supply voltages to the word lines WL0 to WLn, the drain select line DSL, and the source select line SSL in response to an input address ADD when a program operation is performed.

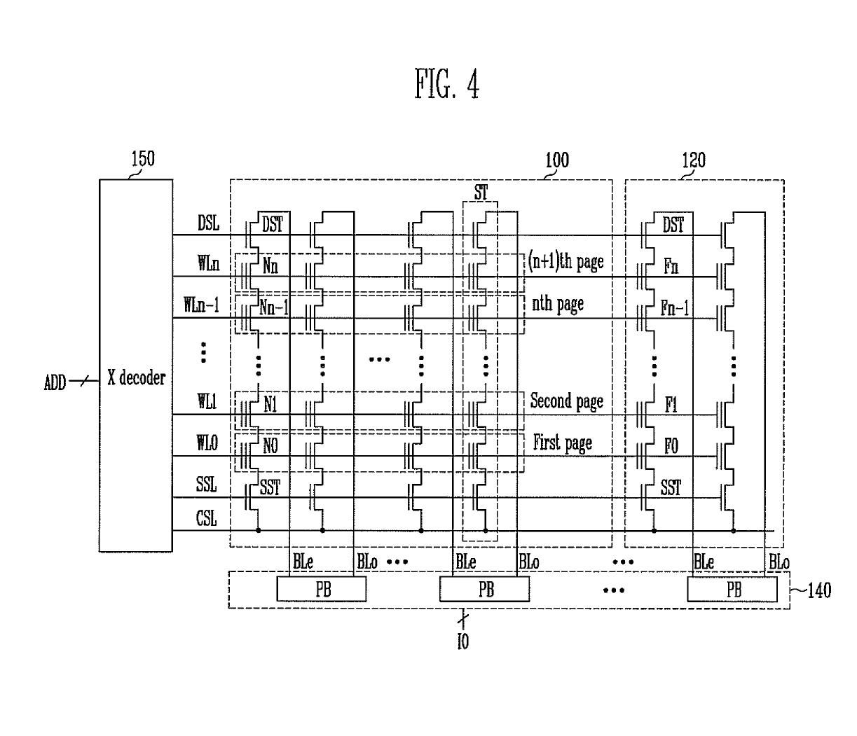

FIG. 3 is a flowchart illustrating a method of programming a nonvolatile memory device according to an exemplary embodiment of this disclosure.

When a method of programming a selected memory cell block is started, an initial program operation is performed so that all the memory cells of the selected memory cell block have threshold voltages of a positive voltage at step 302. After an erase operation for an n^{th} page is performed at step 304, a program operation for the n^{th} page is performed at step 306. It is then determined whether the n^{th} page is the last page of the selected memory cell block at step 308. If, as a result of the determination, the n^{th} page is determined to be the last page of the selected memory cell block, the program operation is terminated. If, as a result of the determination, the n^{th} page is determined not to be the last page of the selected memory cell block, a next page (i.e., an (n+1)^{th} page) is selected at step 310, and the erase and program operations are repeatedly performed on the next page. The method of programming continues until the n^{th} page is the last page. Thus, the erase and program operations may be repeated numerous times.

The above method of programming is described in more detail with reference to FIGS. 2, 3, and 6.

FIG. 6 is a diagram illustrating a shift in the threshold voltages of memory cells when an exemplary method of programming is performed in accordance with this disclosure.

When the method of programming is started, the initial program operation is performed on all the memory cells of the selected memory cell block. More particularly, even though the method of programming is started, an erase operation is not performed on the selected memory cell block. Thus, all the memory cells of the selected memory cell block maintain threshold voltages of a previous state (400 of FIG. 6). In this state, the initial program operation is performed so that the threshold voltages of all the memory cells of the selected memory cell block have a positive voltage. The initial program operation can be performed in accordance with an Incremental Step Pulse Program (ISPP) method. In order to perform the initial program operation, all the bit lines BL are grounded with the drain and source select transistors DST and SST being turned off. Here, a ground voltage preferably is supplied to the common source line CSL. An initial program voltage is supplied to all the word lines WL0 to WLn, and the drain select transistors DST are turned on. In general, the initial program voltage can have a voltage level of a common program voltage or lower, preferably, 18 V to 22 V.

The threshold voltages of all the memory cells of the selected memory cell block are raised by supplying the initial program voltage to all the word lines WL0 to WLn. Next, a verification operation is performed on all the memory cells N0 to Nn of the selected memory cell block. During the verification operation, a reference voltage can be set to a positive voltage of 0 V or higher or can be set to the same level as a first reference voltage PV1, and the reference voltage is lower than that of the initial program voltage. Here, the first reference voltage PV1 refers to a voltage of the lowest program state that a multi-level cell (MLC) may be in.

In a case where the reference voltage is set to 0 V and the initial program operation is performed, a distribution of the threshold voltages of the memory cells ranges from 0 V to the highest level of the threshold voltages (400a of FIG. 6). That is, the threshold voltages of memory cells whose states before the initial program operation are the erase state are raised because of the initial program voltage. However, the threshold voltages of memory cells whose states, before the initial program operation, are the highest program state are no longer raised although the initial program voltage is supplied to the corresponding word lines. Rather, those memory cells, whose states are the highest program state before the initial program operation, maintain their previous threshold voltages. Further, in another case where the initial program operation is performed in response to the first reference voltage PV1 (400b of FIG. 6), the threshold voltages of the memory cells range from the first reference voltage PV1 to the highest level of the threshold voltages.

When all the memory cells of the selected memory cell block are in the initial state (400a or 400b of FIG. 6) (that is, all the threshold voltages of the memory cells become a positive voltage), an erase operation is performed on a selected page (step 304 of FIG. 3 and step (b) of FIG. 6). Here, the page indicates a group of memory cells coupled to the same word line. In order to perform the erase operation of the selected page, an erase voltage is supplied to a well of the selected memory cell block, and a selected word line is grounded or floated. Here, an erase-inhibited voltage is supplied to the remaining word lines other than the selected word line. For example, the erase voltage and the erase-inhibited voltage can have a voltage level of 20 V to 25 V. The page erase operation can be performed in accordance with an Incremental Step Pulse Erase (ISPE) method. After the erase operation of the selected page is performed, the threshold voltages of the memory cells included in the selected page become the erase state (402a of FIG. 6), and the threshold voltages of memory cells included in the remaining unselected pages maintain the initial state (400a or 400b of FIG. 6). Furthermore, after the erase operation of the selected page is completed, data indicative of whether a corresponding page has been erased is stored in a flag cell (i.e., one of the flag cells F0 to Fn) coupled to the word line of the selected page. The stored data is used to determine whether the corresponding page has been erased.

After the erase operation for the selected page is completed (i.e., step (b) of FIG. 6 is completed), a least significant bit program operation is performed on the selected page (step (c) of FIG. 6). During the least significant bit program operation, the unselected memory cells maintain an erase state (404a of FIG. 6), and the selected memory cells are programmed to increase their threshold voltages (404b of FIG. 6). Even after the least significant bit program operation, a verification operation for verifying the completion of the least significant bit program may be performed. If, as a result of the verification operation for the least significant bit program, the threshold voltages of all the least significant bit programmed memory cells have reached a reference voltage of the least significant bit program (i.e., step (c) of FIG. 6 is completed), a most significant bit program operation is performed on the selected page (step (d) of FIG. 6). After the most significant bit program operation is performed, some of the memory cells having the erase state after the least significant bit program operation, maintain an erase state (406a of FIG. 6), and some of them are programmed to be in a first program state (406b of FIG. 6). Furthermore, some of the least significant bit programmed memory cells (i.e., memory cells in state 404b) are programmed to be in a second program state (406c of FIG. 6), and some of the least significant bit programmed memory cells are programmed to be in a third program state (406d of FIG. 6). Even after the most significant bit program operation is performed, a verification operation may be performed to verify the completion of the most significant bit program.

If, as a result of the verification operation of the most significant bit program, the threshold voltages of the selected memory cells have reached a reference voltage of the most significant bit program, the erase operation, the least significant bit program operation, and the most significant bit program operation are performed on a next page. In this manner, the erase operation, the least significant bit program operation, and the most significant bit program operation are performed on all the pages of the selected memory cell block.

FIG. 4 is a circuit diagram showing a memory cell array of a nonvolatile memory device according to another exemplary embodiment of this disclosure.

The nonvolatile memory device includes a memory cell array 100, a flag cell array 120, a page buffer unit 140, and an X decoder 150.

The memory cell array 100 includes a plurality of strings ST. Each of the strings ST includes a drain select transistor DST, a plurality of memory cells N0 to Nn, and a source select transistor SST which are coupled in series. The gates of the drain select transistors DST included in different strings are coupled together to form a drain select line DSL, and the gates of the source select transistors SST included in different strings are coupled together to form a source select line SSL. The gates of the memory cells N0 to Nn of different strings are respectively coupled together to form a plurality of word lines WL0 to WLn. The drains of the drain select transistors DST included in different strings are coupled to respective bit lines BLe or BLo, and the sources of the source select transistors SST included in different strings are commonly coupled to a common source line CSL. A group of memory cells coupled to the same word line, from among the memory cells N0 to Nn, is called a page. Accordingly, the number of pages equals the number of word lines.

The flag cell array 120 includes a plurality of flag cells F0 to Fn for storing data of an erase state for the respective pages. The flag cell array 120 has a similar structure as the memory cell array. More particularly, the flag cell array 120 includes one or more strings each including the flag cells F0 to Fn coupled in series between a drain select transistor DST and a source select transistor SST. Each of the flag cells N0 to Nn can be implemented using a flash memory cell. The drains of the drain select transistors DST of the flag cell array 120 are coupled to the page buffer unit 140 via the respective bit lines BLe or BLo, and the sources of the source select transistors SST thereof are coupled to the common source line CSL.

The page buffer unit 140 includes a plurality of page buffers PB. Each page buffer PB is coupled to two bit lines BLe and BLo. The bit lines BLe and BLo can be classified into a first bit line and a second bit line. The first bit line is called an even bit line and the second bit line is called an odd bit line, for convenience of description. The page buffer unit 140 can supply voltage to the bit lines BLe and BLo in response to data inputted through an I/O terminal IO, or read data stored in the memory cells N0 to Nn or the flag cells F0 to Fn.

The X decoder 150 supplies voltages depending on an operation that is to be programmed. For example, the X decoder 150 may supply voltages to the word lines WL0 to WLn, the drain select line DSL, and the source select line SSL in response to an input address ADD when a program operation is performed.

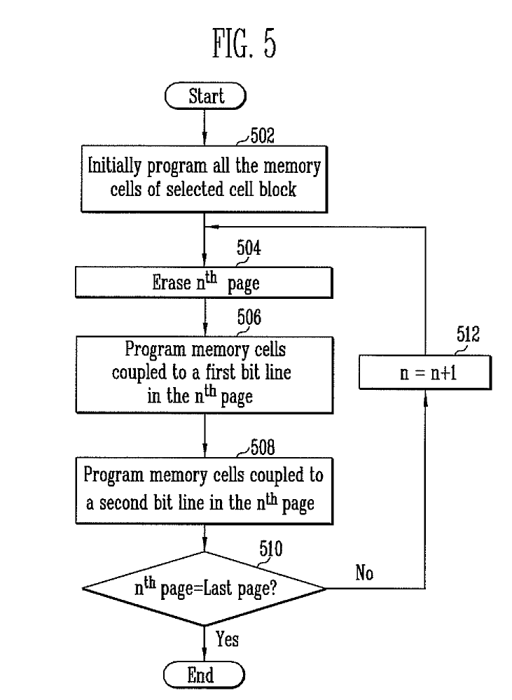

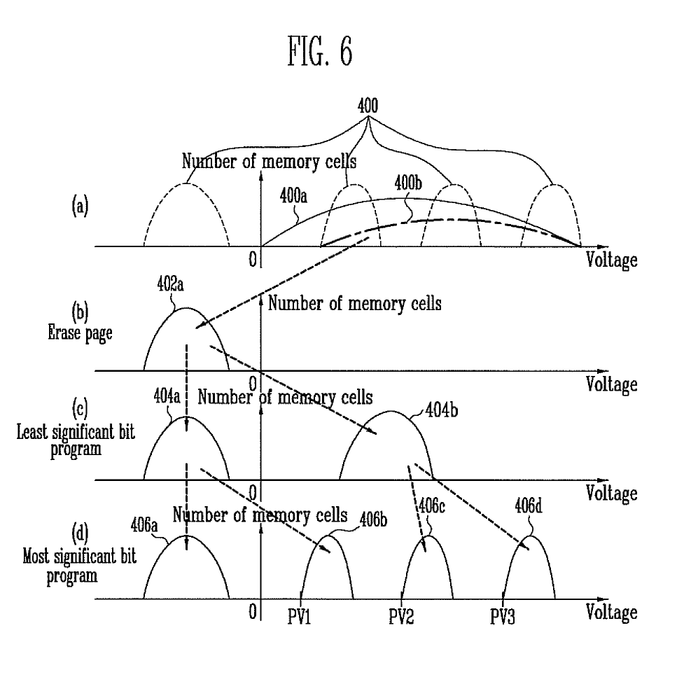

FIG. 5 is a flowchart illustrating a method of programming a nonvolatile memory device according to another exemplary embodiment of this disclosure.

When a method of programming a selected memory cell block is started, an initial program operation is performed so that threshold voltages of all the memory cells of the selected memory cell block have a positive voltage at step 502. After an erase operation is performed on an n^{th} page at step 504, memory cells coupled to the even bit lines BLe in the n^{th} page are programmed at step 506. Next, memory cells coupled to the odd bit lines BLo in the n^{th} page are programmed at step 508. It is then determined whether the n^{th} page is the last page of the selected memory cell block at step 510. If, as a result of the determination, the n^{th} page is determined to be the last page of the selected memory cell block, the program operation is terminated. If, as a result of the determination, the n^{th} page is determined not to be the last page of the selected memory cell block, a next page (i.e., an (n+1)^{th} page) is selected at step 512, and the erase and program operations are repeatedly performed on the next page. The method of programming continues until the n^{th} page is the last page. Thus, the erase and program operations may be repeated numerous times.

The above method of programming is described in more detail with reference to FIGS. 4, 5, and 6. When the method of programming is started, an operation for erasing all the memory cells of the selected memory cell block is not performed, and instead, the initial program operation is performed on all the memory cells of the selected memory cell block at step 502. More particularly, even though the method of programming is started, the erase operation is not yet performed. Thus, all the memory cells of the selected memory cell block maintain threshold voltages of a previous state (400 of FIG. 6). In this state, the initial program operation is performed so that the threshold voltages of all the memory cells of the selected memory cell block have a positive voltage. The initial program operation can be performed in accordance with an Incremental Step Pulse Program (ISPP) method. In order to perform the initial program operation, all the bit lines BLe and BLo are grounded with the drain and source select transistors DST and SST being turned off. Here, a ground voltage preferably is supplied to the common source line CSL. An initial program voltage is supplied to all the word lines WL0 to WLn, and the drain select transistors DST are turned on. In general, the initial program voltage can have a voltage level of a common program voltage or lower, preferably, 18 V to 22 V.

The threshold voltages of all the memory cells of the selected memory cell block are raised by supplying the initial program voltage to all the word lines WL0 to WLn. Next, a verification operation is performed on all the memory cells N0 to Nn of the selected memory cell block. During the verification operation, a reference voltage can be set to a positive voltage of 0 V or higher or can be set to the same level as a first reference voltage PV1. Here, the first reference voltage PV1 refers to a voltage of the lowest program state that a multi-level cell (MLC) may be in.

In a case where the reference voltage is set to 0 V and the initial program operation is performed, a distribution of threshold voltages of the memory cells ranges from 0 V to the highest level of the threshold voltages (400a of FIG. 6). That is, the threshold voltages of memory cells whose states before the initial program operation are the erase state are raised because of the initial program voltage. However, the threshold voltages of memory cells whose states, before the initial program operation, are the highest program state are no longer raised although the initial program voltage is supplied to the corresponding word lines. Rather, those memory cells, whose states are the highest program state before the initial program operation, maintain their previous threshold voltages. Further, in another case where the initial program operation is performed in response to the first reference voltage PV1 (400b of FIG. 6), the threshold voltages of the memory cells range from the first reference voltage PV1, to the highest level of the threshold voltages.

When all the memory cells of the selected memory cell block are in the initial state (400a or 400b of FIG. 6) (that is, all the threshold voltages of the memory cells become a positive voltage), an erase operation is performed on a selected page (step 504 of FIG. 5 and step (b) of FIG. 6). The erase operation is performed to erase all the memory cells of the selected page. That is, the memory cells coupled to the first and second bit lines BLe and BLo in the selected page are erased. The first bit line BLe can be an even bit line, and the second bit line BLo can be an odd bit line.

In order to perform the erase operation of the selected page, an erase voltage is supplied to a well of the selected memory cell block, and a selected word line is grounded or floated. Here, an erase-inhibited voltage is supplied to the remaining word lines other than the selected word line. For example, the erase voltage and the erase-inhibited voltage can have a voltage level of 20 V to 25V. The page erase operation can be performed in accordance with an Incremental Step Pulse Erase (ISPE) method. After the erase operation of the selected page is performed, the threshold voltages of the memory cells included in the selected page become the erase state (402a of FIG. 6), and the threshold voltages of memory cells included in the remaining unselected pages maintain the initial state (400a or 400b of FIG. 6). Furthermore, after the erase operation of the selected page is completed, data indicative of whether a corresponding page has been erased is stored in a flag cell (i.e., one of the flag cells F0 to Fn) coupled to the word line of the selected page. The stored data is used to determine whether the corresponding page has been erased.

After the erase operation of the selected page is completed (i.e., step (b) of FIG. 6 is completed), the program operation is performed on the memory cells coupled to the even bit lines BLe in the selected page at step 506 and then performed on the memory cells coupled to the odd bit lines BLo in the selected page at step 508. That is, the erase operation is not performed between a program operation of memory cells coupled to a bit line selected first from among the even and odd bit lines and a program operation of memory cells coupled to a bit line selected second from among the even and odd bit lines. For example, in case where the even bit line BLe is selected before the odd bit line BLo in order to perform a program operation, an erase operation is performed on a page selected in a time period immediately before memory cells coupled to the even bit line BLe are programmed, but not in a time period immediately before memory cells coupled to the odd bit line BLo are programmed. This is because if the erase operation is performed on the selected page, all the memory cells coupled to the even and odd bit lines BLe and BLo are erased.

Furthermore, in a case where a least significant bit program operation and a most significant bit program operation are performed, after the erase operation of the selected page is performed at step 504, the least significant bit program operation is performed on the memory cells coupled to the even bit lines BLe (step (c) of FIG. 6). During the least significant bit program operation, the unselected memory cells maintain the erase state (404a of FIG. 6), and the selected memory cells are programmed to increase their threshold voltages (404b of FIG. 6). Even after the least significant bit program operation, a verification operation for the least significant bit program may be performed. If, as a result of the verification operation for the least significant bit program, the threshold voltages of all the least significant bit programmed memory cells have reached a reference voltage of the least significant bit program (i.e., step (c) of FIG. 6 is completed), the most significant bit program operation is performed on the memory cells coupled to the even bit lines BLe in the selected page (step (d) of FIG. 6). After the most significant bit program operation is performed, some of the memory cells having the erase state after the least significant bit program operation, maintain the erase state (406a of FIG. 6), and some of them are programmed to be in the first program state (406b of FIG. 6). Furthermore, some of the least significant bit programmed memory cells (i.e., memory cells in state 404b) are programmed to be in the second program state (406c of FIG. 6), and some of them are programmed to be in the third program state (406d of FIG. 6). Even after the most significant bit program operation is performed, a verification operation for the most significant bit program may be performed.

If, as a result of the verification operation for the most significant bit program, the threshold voltages of the selected memory cells have reached a reference voltage of the most significant bit program, the least significant bit and most significant bit program operations are performed on the memory cells coupled to the odd bit lines BLo in the selected page are performed.

If threshold voltages of all the memory cells of the selected page have reached a reference voltage, a next page is selected at step 512, and the erase operation, the least significant bit program operation, and the most significant bit program operation are performed on the next page. As described above, the erase operation, the least significant bit program operation, and the most significant bit program operation are performed on all the pages of the selected memory cell block.

As described above, after all the memory cells of a selected memory cell block are programmed with threshold voltages of a positive voltage, erase and program operations are performed on a selected page. Accordingly, during the program operation, the difference between the threshold voltages of memory cells is reduced because the threshold voltages of memory cells adjacent to a selected memory cell have a positive voltage. Consequently, since the difference between the threshold voltages of neighboring memory cells is reduced although a program operation is performed, interference between memory cells can be reduced.

In accordance with the present disclosure, the difference between the threshold voltages of selected memory cells and their neighboring memory cells is reduced when the selected memory cells are programmed. Accordingly, interference between neighboring memory cells resulting from a difference in the threshold voltage can be reduced, and so reliability of a program operation can be improved.

What is claimed is:

1. A method of programming a semiconductor device, comprising:
performing an initial program operation on all memory cells included in a selected memory cell block to set threshold voltages of all the memory cells to a reference voltage;
erasing memory cells of a selected page in the selected memory cell block; and
programming the memory cells of the selected page of the selected memory cell block.

2. The method of claim 1, wherein the initial program operation is performed by an Incremental Step Pulse Program (ISPP) method.

3. The method of claim 1, wherein the initial program operation includes:
applying an initial program voltage to all word lines of the selected memory cell block; and
performing a verification operation for determining whether the threshold voltages of the all the memory cells of the selected memory cell block have reached the reference voltage.

4. The method of claim 3, wherein all bit lines coupled to the selected memory cell block are grounded during the initial program operation.

5. The method of claim 3, wherein a voltage level of the reference voltage is lower than that of the initial program voltage.

6. The method of claim 1, wherein a voltage level of the reference voltage is equal to or greater than 0 Volts.

7. The method of claim 4, further comprising:
applying a ground voltage to a bit line coupled to the selected cell block; and
applying a program inhibit voltage to a remaining bit line,
wherein each bit lines are coupled to each page buffers respectively, when the programming the memory cells of the selected page in the selected memory cell block.

8. The method of claim 3, further comprising:
applying a ground voltage to a bit line coupled to a selected word lime of the selected cell block; and
applying a program inhibit voltage to a remaining bit line,
wherein a even bit line and an odd bit line are coupled to a page buffer, when the programming the memory cells of the selected page in the selected memory cell block.

9. The method of claim 1, further comprising:
performing the erasing and the programming memory cells of a next selected page until the selected page is a last page of the selected memory cell block after the programming the memory cells of the selected page in the selected memory cell block.

10. The method of claim 1, wherein threshold voltages of the all memory cells in the selected memory cell block are maintained at a level of a previous state before the performing the initial program operation.

11. A method of programming a semiconductor device, comprising:
performing an initial program operation on all memory cells included in a selected memory cell block to set threshold voltages of all the memory cells to a reference voltage;
erasing memory cells of a selected page in the selected memory cell block;
performing a least significant bit program operation on the memory cells of the selected page of the selected memory cell block; and
performing a most significant bit program operation on the memory cells of the selected page of the selected memory cell block.

12. The method of claim 11, wherein the initial program operation is performed by an Incremental Step Pulse Program (ISPP) method.

13. The method of claim 11, wherein the initial program operation includes:
applying an initial program voltage to all word lines of the selected memory cell block; and
performing a verification operation for determining whether the threshold voltages of the all the memory cells of the selected memory cell block have reached the reference voltage.

14. The method of claim 13, wherein all bit lines coupled to the selected memory cell block are grounded during the initial program operation.

15. The method of claim 13, wherein a voltage level of the reference voltage is lower than that of the initial program voltage.

16. The method of claim 11, wherein a voltage level of the reference voltage is equal to or greater than 0 Volts.

17. The method of claim 14, further comprising:
applying a ground voltage to a bit line coupled to the selected cell block; and
applying a program inhibit voltage to a remaining bit line,
wherein each bit lines are coupled to each page buffers respectively, when the programming the memory cells of the selected page in the selected memory cell block.

18. The method of claim 14, further comprising:
applying a ground voltage to a bit line coupled to the selected cell block; and
applying a program inhibit voltage to a remaining bit line,
wherein a even bit line and an odd bit line are coupled to a page buffer, when the programming the memory cells of the selected page in the selected memory cell block.

19. The method of claim 11, wherein threshold voltages of the all memory cells in the selected memory cell block are maintained at a level of a previous state before the performing the initial program operation.
